(19) United States
(12) Patent Application Publication
(10) Pub. No.: US 2025/0089282 A1
(43) Pub. Date: Mar. 13, 2025

(54) Diode and Method of Manufacturing Same

(71) Applicant: Microchip Technology Incorporated, Chandler, AZ (US)

(72) Inventors: Shesh Mani Pandey, Gilbert, AZ (US); Bruce Odekirk, Portland, OR (US)

(73) Assignee: Microchip Technology Incorporated, Chandler, AZ (US)

(21) Appl. No.: 18/733,611

(22) Filed: Jun. 4, 2024

Related U.S. Application Data
(60) Provisional application No. 63/537,151, filed on Sep. 7, 2023.

(51) Int. Cl. H01L 29/872; H01L 29/06; H01L 29/167; H01L 29/66

(52) U.S. Cl. CPC H10D 8/60; H10D 8/051; H10D 62/102; H10D 62/834

(57) ABSTRACT

A diode that may include a substrate with a cathode terminal on a first surface of the substrate. An anode terminal on a second surface of the substrate. An implant portion disposed within the substrate.

### CROSS-REFERENCE TO RELATED APPLICATION

The present application claims priority to U.S. Provisional Patent Application No. 63/537,151, filed on Sep. 7, 2023, the contents of which are hereby incorporated by reference in their entirety.

### TECHNICAL FIELD

The present disclosure relates generally to diodes, and more specifically to the structure of a Schottky barrier diode and methods of manufacturing same.

### SUMMARY

According to an aspect of one or more examples, there is provided a diode that may include a substrate, a cathode terminal on a first surface of the substrate, an anode terminal on a second surface of the substrate, and an implant portion disposed within the substrate. The diode may be a Schottky barrier diode. The substrate of the diode may be made of an n-type semiconductor. The implant portion of the diode may comprise a p-type semiconductor. The implant portion of the diode may comprise a circular shape, a rectangular shape, a triangular shape, a pentagonal shape, a hexagonal shape, or an octagonal shape.

According to an aspect of one or more examples, there is provided a diode that may include a substrate, a cathode terminal on a first surface of the substrate, an anode terminal on a second surface of the substrate, a first implant portion having a first concentration disposed within the substrate, and a second implant portion having a second concentration disposed within the first implant portion wherein the first implant portion encompasses the second implant portion, wherein the second concentration is not equal to the first concentration. The diode may be a Schottky barrier diode. The substrate of the diode may be made of an n-type semiconductor. The first implant portion of the diode may comprise a p-type semiconductor. The first implant portion of the diode may comprise a circular shape, a rectangular shape, a triangular shape, a pentagonal shape, a hexagonal shape, or an octagonal shape. The second implant portion may comprise a shape generally corresponding to the shape of the first implant portion.

According to an aspect of one or more examples, there is provided a method for manufacturing a diode. The method may include providing a substrate, forming a cathode terminal on a first surface of the substrate, forming an anode terminal on a second surface of the substrate; and forming an implant portion by implanting a semiconductor material into the substrate. The method of manufacturing the diode may be for a Schottky barrier diode. The substrate of the method of manufacturing the diode may be made of an n-type semiconductor. The implant portion of the method of manufacturing the diode may be made of a p-type semiconductor. The implant portion of the method of manufacturing the diode may comprise a circular shape, a rectangular shape, a triangular shape, a pentagonal shape, a hexagonal shape, or an octagonal shape.

According to an aspect of one or more examples, there is provided a method for manufacturing a diode. The method may include providing a substrate, forming a cathode terminal on a first surface of the substrate, forming an anode terminal on a second surface of the substrate; forming a first implant portion by implanting a first concentration of semiconductor material into the substrate, and forming a second implant portion by implanting a second concentration of semiconductor material into the first implant portion wherein the first implant portion encompasses the second implant portion, wherein the second concentration is not equal to the first concentration. The method of manufacturing the diode may be for a Schottky barrier diode. The substrate of the method of manufacturing the diode may be made of an n-type semiconductor. The first implant portion and the second implant portion of the method of manufacturing the diode may be made of a p-type semiconductor. The first implant portion of the method of manufacturing the diode may comprise a circular shape, a rectangular shape, a triangular shape, a pentagonal shape, a hexagonal shape, or an octagonal shape. The second implant portion of the method of manufacturing the diode may comprise a shape generally corresponding to the shape of the first implant portion.

### BRIEF DESCRIPTION OF DRAWINGS

FIG. 1 shows a cross-section view of the diode with an implant portion according to the one or more examples.

FIG. 2A shows a top view of a diode having a circular shaped implant portion according one or more examples.

FIG. 2B shows a top view of a diode having a rectangular shaped implant portion according one or more examples.

FIG. 2C shows a top view of a diode having a triangular shaped implant portion according one or more examples.

FIG. 2D shows a top view of a diode having a pentagonal shaped implant portion according one or more examples.

FIG. 2E shows a top view of a diode having a hexagonal shaped implant portion according one or more examples.

FIG. 2F shows a top view of a diode having a octagonal shaped implant portion according one or more examples.

FIG. 3 shows a cross-section view of the diode having a first implant portion and a second implant portion within the first implant portion according to the one or more examples.

FIG. 4A shows a top view of a diode having circular shaped implant portions according one or more examples.

FIG. 4B shows a top view of a diode having rectangular shaped implant portions according one or more examples.

FIG. 4C shows a top view of a diode having triangular shaped implant portions according one or more examples.

FIG. 4D shows a top view of a diode having pentagonal shaped implant portions according one or more examples.

FIG. 4E shows a top view of a diode having hexagonal shaped implant portions according one or more examples.

FIG. 4F shows a top view of a diode having octagonal shaped implant portions according one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be in various forms without being limited to the examples set forth herein.

Diodes are used in a variety of applications, such as rectification, wave shaping, and logic gates. While existing diodes may exhibit low power consumption and fast switching speeds, they may allow substantial pre-avalanche leakage current, and may have an unstable breakdown voltage. Therefore, there is a need for a diode design that may address one or more of these issues.

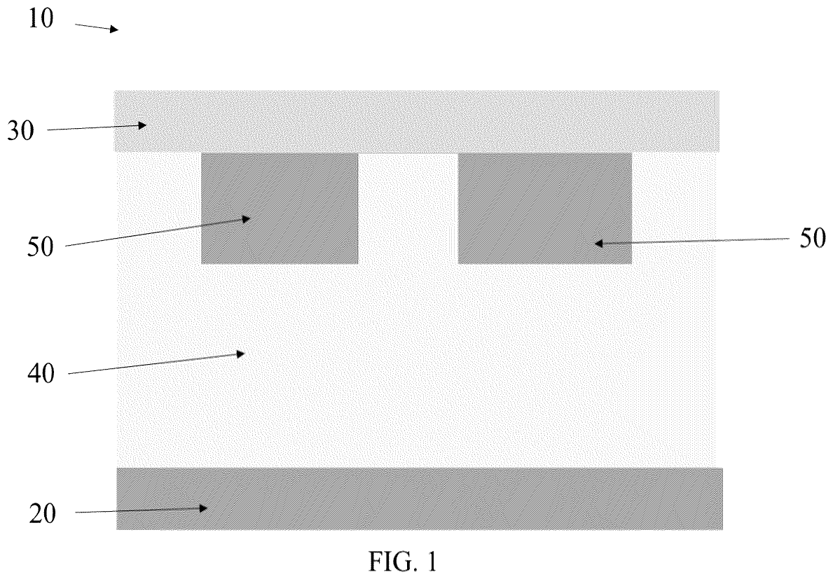

FIG. 1 shows a cross-section view of a diode 10 according to the one or more examples. As shown in FIG. 1, the diode 10 according to the example may include a substrate 40 with a cathode terminal 20 on a first surface of the substrate 40 and an anode terminal 30 on a second surface of the substrate 40, the second surface opposing the first surface. Both the cathode terminal 20 and the anode terminal 30 may be respectively made of a metal, a silicon and metal compound such as silicide, or other suitable material. The substrate 40 may be made of an n-type semiconductor material such as n-doped silicon. The diode 10 may also include an implant portion 50 disposed within the substrate 40. The implant portion 50 may be formed of a p-type semiconductor, such as p-doped silicon. The p-type implant portion 50 may encompass a portion of the n-type substrate 40 may reduce leakage current and may improve breakdown voltage stability of the diode 10.

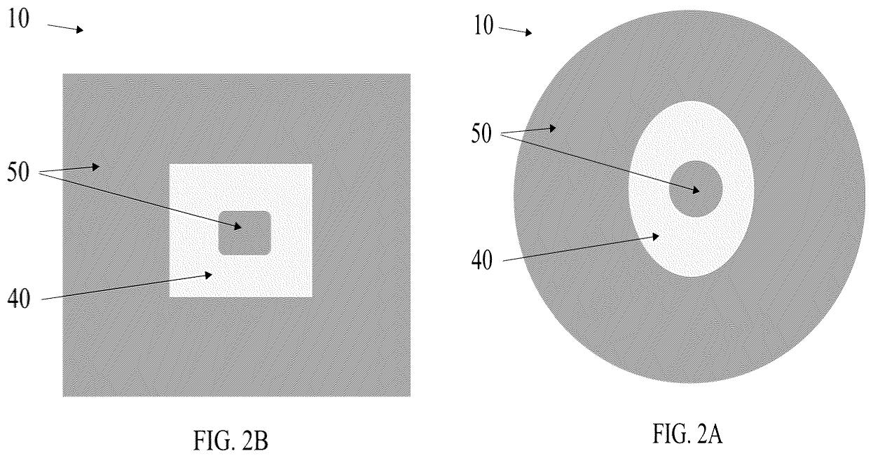

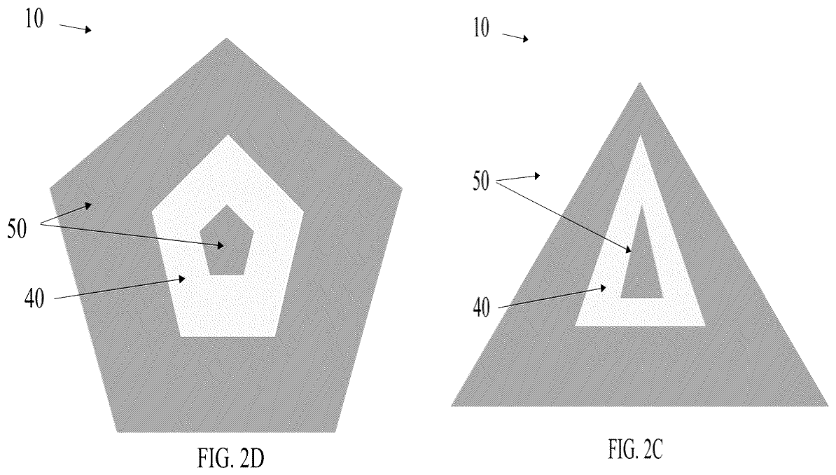

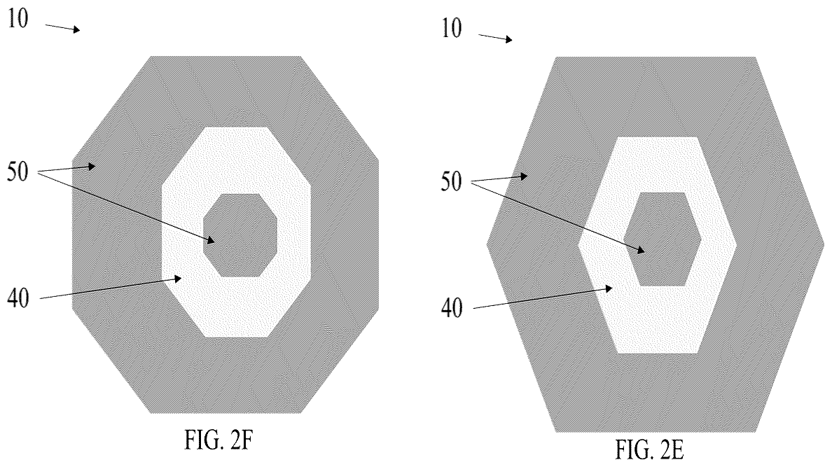

FIG. 2A shows a top view of a diode 10 according one or more examples. In FIG. 2A, the implant portion 50 may be formed in a generally circular shape, the first implant portion 50 thereby encompassing a ring shaped portion of the n-type substrate 40.

FIG. 2B shows a top view of a diode 10 according one or more examples. In FIG. 2B, the implant portion 50 may be formed in a generally rectangular shape, thereby encompassing a rectangular shaped portion of the n-type substrate 40.

FIG. 2C shows a top view of a diode 10 according one or more examples. In FIG. 2C, the implant portion 50 may be formed in a generally triangular shape thereby encompassing a triangularly shaped portion of the n-type substrate 40.

FIG. 2D shows a top view of a diode 10 according one or more examples. In FIG. 2D, the implant portion 50 may be formed in a generally pentagonal shape, thereby encompassing a generally pentagonally shaped portion of the n-type substrate 40.

FIG. 2E shows a top view of a diode 10 according one or more examples. In FIG. 2E, the implant portion 50 may be formed in a generally hexagonal shape, thereby encompassing a generally hexagonally shaped portion of the n-type substrate 40.

FIG. 2F shows a top view of a diode 10 according one or more examples. In FIG. 2F, the implant portion 50 may be formed in a generally octagonal shape, thereby encompassing a generally octagonally shaped portion of the n-type substrate 40.

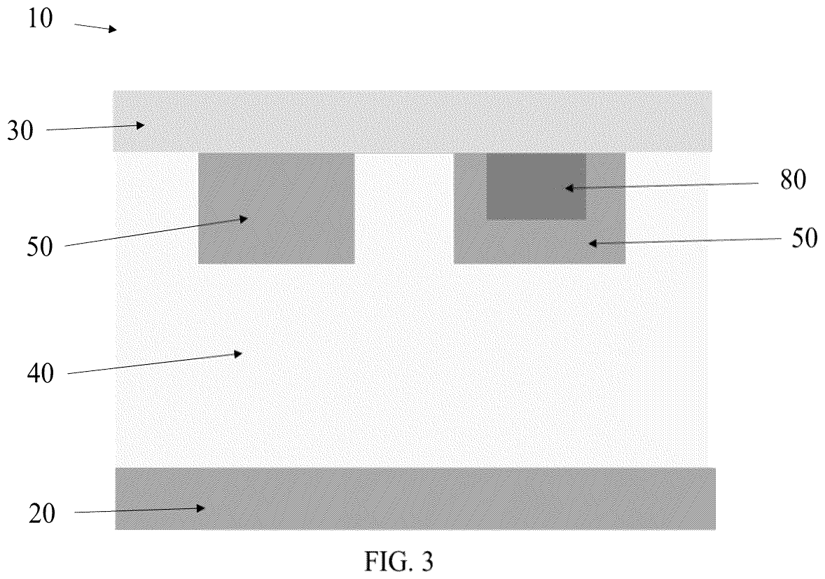

FIG. 3 shows a cross-section view of a diode 10 according to the one or more examples. As shown in FIG. 3, the diode 10 according to the example may include a substrate 40 with a cathode terminal 20 on a first surface of the substrate 40 and an anode terminal 30 on a second surface of the substrate 40, the first surface opposing the second surface. Both the cathode terminal 20 and the anode terminal 30 may be respectively made of a metal, a silicon and metal compound such as silicide, or other suitable material. The substrate 40 may be made of an n-type semiconductor material such as n-doped silicon. The diode 10 may also include a first implant portion 50 having a first concentration that may be formed of a p-type semiconductor, such as p-doped silicon. The first implant portion 50 may be formed within the substrate 40. The diode 10 may also include a second implant portion 80 having a second concentration that may be formed of a p-type semiconductor, such as p-doped silicon. The second concentration of the second implant portion 80 is not equal to the first concentration of the first implant portion 50. The second concentration of the second implant portion 80 may be 2 to 20 times greater than the first concentration of the first implant portion 50. The second implant portion 80 may be formed within the first implant portion 50. By forming the p-type first implant portion 50 and p-type second implant portion to encompass a portion of the n-type substrate, the first implant portion 50 and second implant portion 80 may reduce leakage current and may improve breakdown voltage stability.

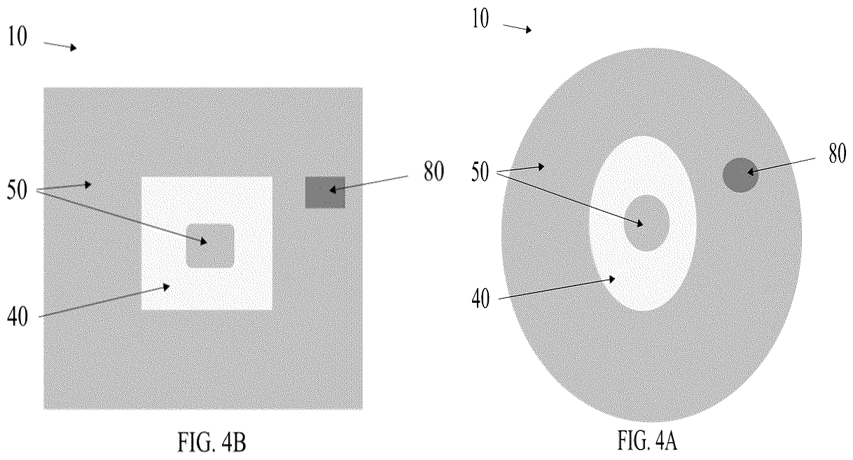

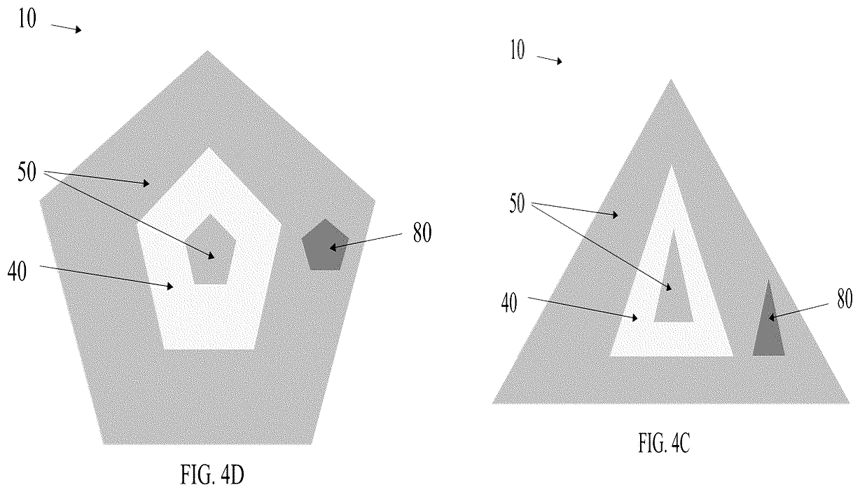

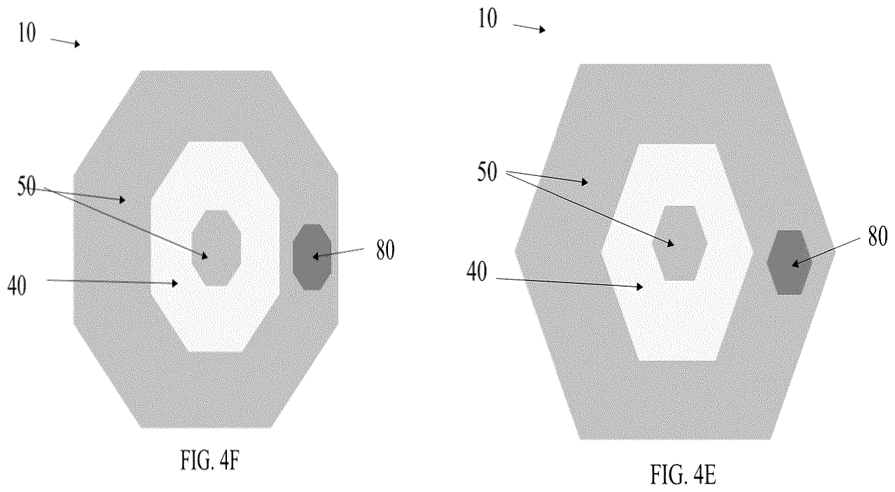

FIG. 4A shows a top view of a diode 10 according one or more examples. In FIG. 4A, the diode 10 may include a first implant portion 50 having a first concentration that may be formed of a p-type semiconductor, such as p-doped silicon and a second implant portion 80 having a second concentration that may be formed of a p-type semiconductor, such as p-doped silicon that may be formed in a generally circular shape, thereby encompassing a generally ring shaped portion of the n-type substrate 40. The second implant portion 80 may thus comprise a shape generally corresponding to the shape of the first implant portion 50. The second concentration of the second implant portion 80 is not equal to the first concentration of the first implant portion 50. The second concentration of the second implant portion 80 may be 2 to 20 times greater than the first concentration of the first implant portion 50.

FIG. 4B shows a top view of a diode 10 according one or more examples. In FIG. 4B, the diode 10 may include a first implant portion 50 having a first concentration that may be formed of a p-type semiconductor, such as p-doped silicon and a second implant portion 80 having a second concentration that may be formed of a p-type semiconductor, such as p-doped silicon that may be formed in a generally rectangular shape, the first implant portion 50 thereby encompassing a generally square shaped portion of the n-type substrate 40. The second implant portion 80 may thus comprise a shape generally corresponding to the shape of the first implant portion 50. The second concentration of the second implant portion 80 is not equal to the first concentration of the first implant portion 50. The second concentration of the second implant portion 80 may be 2 to 20 times greater than the first concentration of the first implant portion 50.

FIG. 4C shows a top view of a diode 10 according one or more examples. In FIG. 4C, the diode 10 may include a first implant portion 50 having a first concentration that may be formed of a p-type semiconductor, such as p-doped silicon and a second implant portion 80 having a second concentration that may be formed of a p-type semiconductor, such as p-doped silicon that may be formed in a generally triangular shape, the first implant portion 50 thereby encompassing a triangularly shaped portion of the n-type substrate 40. The second implant portion 80 may thus comprise a shape generally corresponding to the shape of the first implant portion 50. The second concentration of the second implant portion 80 is not equal to the first concentration of the first implant portion 50. The second concentration of the second implant portion 80 may be 2 to 20 times greater than the first concentration of the first implant portion 50.

FIG. 4D shows a top view of a diode 10 according one or more examples. In FIG. 4D, the diode 10 may include a first implant portion 50 having a first concentration that may be formed of a p-type semiconductor, such as p-doped silicon and a second implant portion 80 may be formed in a generally pentagonal shape, the first implant portion 50 thereby encompassing a generally pentagonally shaped portion of the n-type substrate 40. The second implant portion 80 having a second concentration that may be formed of a p-type semiconductor, such as p-doped silicon that may thus comprise a shape generally corresponding to the shape of the first implant portion 50. The second concentration of the second implant portion 80 is not equal to the first concentration of the first implant portion 50. The second concentration of the second implant portion 80 may be 2 to 20 times greater than the first concentration of the first implant portion 50.

FIG. 4E shows a top view of a diode 10 according one or more examples. In FIG. 4E, the diode 10 may include a first implant portion 50 having a first concentration that may be formed of a p-type semiconductor, such as p-doped silicon and a second implant portion 80 having a second concentration that may be formed of a p-type semiconductor, such as p-doped silicon that may be formed in a generally hexagonal shape, the first implant portion 50 thereby encompassing a generally hexagonally shaped portion of the n-type substrate 40. The second implant portion 80 may thus comprise a shape generally corresponding to the shape of the first implant portion 50. The second concentration of the second implant portion 80 is not equal to the first concentration of the first implant portion 50. The second concentration of the second implant portion 80 may be 2 to 20 times greater than the first concentration of the first implant portion 50.

FIG. 4F shows a top view of a diode 10 according one or more examples. In FIG. 4F, the diode 10 may include a first implant portion 50 having a first concentration that may be formed of a p-type semiconductor, such as p-doped silicon and a second implant portion 80 having a second concentration that may be formed of a p-type semiconductor, such as p-doped silicon that may be formed in a generally octagonal shape, the first implant portion 50 thereby encompassing a generally octagonally shaped portion of the n-type substrate 40. The second implant portion 80 may thus comprise a shape generally corresponding to the shape of the first implant portion 50. The second concentration of the second implant portion 80 is not equal to the first concentration of the first implant portion 50. The second concentration of the second implant portion 80 may be 2 to 20 times greater than the first concentration of the first implant portion 50.

Various examples have been disclosed herein, in connection with the above description and the drawings. It will be understood that it would be unduly repetitious to literally describe and illustrate every combination and subcombination of these examples. Accordingly, all examples can be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A diode comprising:
a substrate;
a cathode terminal on a first surface of the substrate;
an anode terminal on a second surface of the substrate; and
an implant portion disposed within the substrate.

2. The diode of claim 1, wherein the substrate comprises an n-type semiconductor.

3. The diode of claim 2, wherein the implant portion comprises a p-type semiconductor.

4. The diode of claim 1, wherein the implant portion comprises a circular shape, a rectangular shape, a triangular shape, a pentagonal shape, a hexagonal shape, or an octagonal shape.

5. A diode comprising:
a substrate;
a cathode terminal on a first surface of the substrate;
an anode terminal on a second surface of the substrate;
a first implant portion having a first concentration disposed within the substrate; and
a second implant portion having a second concentration disposed within the first implant portion wherein the first implant portion encompasses the second implant portion, wherein the second concentration is not equal to the first concentration.

6. The diode of claim 5, wherein the second concentration of the second implant portion is 2 to 20 times greater than the first concentration of the first implant portion.

7. The diode of claim 5, wherein the substrate comprises an n-type semiconductor.

8. The diode of claim 7, wherein the first implant portion and the second implant portion comprises a p-type semiconductor.

9. The diode of claim 5, wherein the first implant portion comprises a circular shape, a rectangular shape, a triangular shape, a pentagonal shape, a hexagonal shape, or a octagonal shape.

10. The diode of claim 9, wherein the second implant portion comprises a shape generally corresponding to the shape of the first implant portion.

11. A method of manufacturing a diode, the method comprising:
providing a substrate;
forming a cathode terminal on a first surface of the substrate;
forming an anode terminal on a second surface of the substrate; and
forming an implant portion by implanting a semiconductor material into the substrate.

12. The method of claim 11, wherein the substrate comprises an n-type semiconductor.

13. The method of claim 12, wherein the implant portion comprises a p-type semiconductor.

14. The method of claim 11, wherein the implant portion comprises a circular shape, a rectangular shape, a triangular shape, a pentagonal shape, a hexagonal shape, or a octagonal shape.

15. A method of manufacturing a diode, the method comprising:
providing a substrate;
forming a cathode terminal on a first surface of the substrate;
forming an anode terminal on a second surface of the substrate;
forming a first implant portion by implanting a first concentration of semiconductor material into the substrate; and
forming a second implant portion by implanting a second concentration of semiconductor material into the first implant portion wherein the first implant portion encompasses the second implant portion, wherein the second concentration is not equal to the first concentration.

16. The method of claim 15, wherein the second concentration of the second implant portion is 2 to 20 times greater than the first concentration of the first implant portion.

17. The method of claim 15, wherein the substrate comprises an n-type semiconductor.

18. The method of claim 16, wherein the first implant portion and the second implant portion comprises a p-type semiconductor.

19. The method of claim 15, wherein the first implant portion comprises a circular shape, a rectangular shape, a triangular shape, a pentagonal shape, a hexagonal shape, or an octagonal shape.

20. The method of claim 19, wherein the second implant portion comprises a shape generally corresponding to the shape of the first implant portion.
